(19) United States
(12) Patent Application Publication
(10) Pub. No.: US 2006/0245172 A1
(43) Pub. Date: Nov. 2, 2006

(54) CIRCUIT BOARDS

(75) Inventor: Steve Van Kirk, Brooklyn Park, MN (US)

Correspondence Address: SCHWEGMAN, LUNDBERG, WOESSNER & KLUTH, P.A., P.O. BOX 2938, MINNEAPOLIS, MN, 55402, US

(73) Assignee: Micron Technology, Inc.

(21) Appl. No.: 11/427,737

(22) Filed: Jun. 29, 2006

Related U.S. Application Data
(62) Division of application No. 09/945,394, filed on Aug. 30, 2001.

(51) Int. Cl. H05K 7/12

(52) U.S. Cl. 361/767

(57) ABSTRACT

A circuit board may include a first conductive layer having a first interstice and a third interstice; a second conductive layer having a second interstice engaged with the first interstice, and a fourth interstice engaged with the third interstice; and a dielectric layer disposed between the first and third interstices, and the second and fourth interstices. The conductive layers may be sinuously intertwined.

### RELATED APPLICATIONS

This application is a Divisional of Ser. No. 09/945,394, filed Aug. 30, 2001, which is incorporated herein by reference.

### TECHNICAL FIELD

This disclosure relates generally to electrical circuitry mounted to printed circuit boards, including various apparatus, methods, and systems which affect the performance of high-speed signal processing circuitry attached to multi-layer printed circuit boards.

### BACKGROUND

Steady advances in integrated circuit technology have fueled the last 30 years of increasingly rapid progress with regard to the speed and complexity of signal processing circuitry design. In the past, system processing speed was determined by gate and register performance. Thus, to increase the speed and power of a particular circuit, one might simply select faster, more complex, and even less expensive integrated circuits.

Given these circumstances, the printed circuit board merely served as a mechanism for holding integrated circuits in place. Printed circuit board layout was fundamentally an exercise in topology and economics. Analog circuit design issues, such as crosstalk, phase distortion, amplitude distortion, reflections, ringing, ground bounce, and so on could be safely ignored. At worst, such events were treated as minor irritants. This was the case because synchronous digital logic is fairly forgiving with regard to amplitude and timing variations, especially at slow clock speeds.

Times and circumstances have changed. At current typical operational speeds, the printed circuit board and its analog characteristics play a strong, if not dominating role in determining overall digital system performance.

Complementary metal oxide semiconductor (CMOS) integrated circuits no longer represent the slow, forgiving circuits of the past. They are now as fast as (if not faster than) the fastest transistor-transistor logic (TTL) circuits. CMOS outputs leap between zero and five volts in 1 nanosecond or less, and clock rates exceed several hundred megahertz. Some integrated circuits have up to 500 signal connections accommodating multiple 32-bit wide buses. The trend is moving toward higher speeds, and ever-increasing numbers of input- output circuit connections.

However, signals still travel along printed circuit board traces at only half the speed of light. Sharp signal edges get reflected at every trace discontinuity. Not only must the source to destination path be controlled, but attention must also be paid to each complete circuit loop and its inductance. That is, from the positive power supply terminal, through the supply to the negative supply terminal, through various capacitances and inductances by way of the circuit traces and operational circuitry, then through various decoupling capacitors, and back to the positive supply terminal.

This means that the printed circuit board plays an important role in controlling the integrity of interconnect signals. Trace width and trace spacing, controlled line impedance, and multi-layer boards with clean ground and power planes are all required to minimize reflections, stray emissions, ground bounce, and crosstalk.

Conventional wisdom recommends applying ceramic decoupling capacitors in parallel with power and ground planes to lower impedance. In fact, some texts recommend adding coupling capacitors to terminating resistors to prevent signal degradation due to reflections (ringing).

Power supply systems typically make use of a large electrolytic capacitor to smooth out gross voltage variations. Such capacitors typically have a large inductance. Therefore, low-impedance ceramic decoupling capacitors are usually required to supply dynamically changing currents inside integrated circuit chips, and to provide a return path for external current changes. Especially for CMOS circuit systems, all power is dynamic. The instantaneous current peaks are much higher than the average DC current. In such systems, most preferably, effective decoupling capacitors should be selected so as to have a low inductance and a low series resistance. Thus, power supply decoupling, using a plurality of external capacitors, is not a luxury—it is a necessity.

Referring now to the prior art depicted in FIG. 1, a perspective view of the general problem, illustrated using a multi-layer circuit board with two power planes, can be seen. It is now common practice to use multiple power planes in low-power, high-speed circuit design. Thus, for example, a +3.3V power plane 30 and a +2.5V power plane 40 may be used to power a microprocessor or memory module mounted on a printed circuit motherboard. Typically, the +3.3V power supply 34 is connected between the power plane 30 and the ground plane 25. The +2.5V power supply 44 is also connected to its respective power plane 40, and the ground plane 25. As high speed signal currents 43 are driven from the power plane 40 to the power plane 30, from pad 42 to pad 32, for example, high speed return currents 46 attempt to traverse the inherent capacitance 48 which exists between the planes 30, 40. Since the value of the capacitance 48 is usually quite low, and thus unable to supply the energy required for the fall value of the return current 46, other currents 33, 36, and 37 arise, possibly traveling through the physical bypass capacitors 35, 45 and the ground plane 25 in order to close the loop created by the power supplies 34, 44 and the signal currents 43. Generation of the currents 33, 36, 37, and 46 is a high-speed signal phenomenon, and the magnitude of these currents is a function of the signal current 43 clock edge-rate. In any event, however, the existence of the currents 33, 36, 37, and 46 is usually a nuisance, and often compromises the integrity of the signal currents 43, as well as other signals, by way of crosstalk and ground bounce.

Attempting to control wayward currents and extraneous emissions which result using conventional bypass capacitors gives rise to another problem. Referring now to the top view of a prior art circuit board 48 shown in FIG. 2, as well as the side, cut-away view of the same prior art circuit board 48 shown in FIG. 3, the difficulty can easily be seen. In this case, a decoupling capacitor 80 is connected to a first power plane (e.g., a +3.3V plane) 60 and a second power plane (e.g., a +2.5V plane) 70 using the capacitor terminals 82, 84 soldered to the pads 52, 54 and the vias 62, 72, respectively. The pads 52, 54 do not contact the circuit layer 50, which may be a ground layer, for example, due to isolation lands 49. As is well known to those skilled in the art, however, the vias 62, 72 required to connect the capacitor 80 to the power planes 60, 70 make it physically impossible to place any other circuit traces within the same space occupied by the capacitor 80, or to route any signals through the space occupied by the vias 62, 72. The problem is compounded wherever multiple bypass or decoupling capacitors are used.

Using higher processing speeds and more powerful circuitry provides a greater number of signals to be processed, including (relatively) high current input-output signals. However, just as this advance in technology creates a greater need for board real estate to route increasingly greater numbers of signals, there is a corresponding need to increase the number of surface-mounted capacitors to control resulting stray return currents. These considerations give rise to a need in the art to provide an alternative to physical bypass capacitors to introduce capacitive current return paths into current circuit board designs without simultaneously reducing printed circuit board real estate and signal routing path availability.

### BRIEF DESCRIPTION OF THE DRAWINGS

FIG. 1, previously described, is a prior art perspective view of a circuit board with two power planes.

FIG. 2, previously described, is a prior art top plan view of a circuit board and decoupling capacitor.

FIG. 3, previously described, is a prior art side, cut-away view of the circuit board and decoupling capacitor shown in FIG. 2.

FIG. 4A is a top plan (or side cut-away) view of one embodiment of a circuit board of the present invention.

FIG. 4B is a detailed view of one embodiment of the engaged interstices of the circuit board of the present invention, as shown in FIG. 4A.

FIG. 5 is a top plan (or side cut-away) view of another embodiment of a circuit board of the present invention, illustrating a plurality of rectangular interstices.

FIG. 6 is a top plan (or side cut-away) view of another embodiment of a circuit board of the present invention, illustrating triangular interstices.

FIG. 7 is a top plan (or side cut-away) view of another embodiment of a circuit board of the present invention, illustrating circular interstices.

FIG. 8 is a top plan (or side cut-away) view of another embodiment of a circuit board of the present invention, illustrating spiral interstices.

FIG. 9 is a top plan (or side cut-away) view of another embodiment of a circuit board of the present invention, illustrating U-shaped interstices.

FIG. 10 is a top plan (or side cut-away) view of another embodiment of a circuit board of the present invention, illustrating multiple, non-complementary interstices.

FIG. 11 is a top plan (or side cut-away) view of another embodiment of a circuit board of the present invention, illustrating a plurality of graded depth rectangular interstices.

FIG. 12 is a top plan view of another embodiment of a circuit board of the present invention, illustrating substantially overlapping widths between the conducting layers.

FIG. 13 is a top plan (or side cut-away) view of another embodiment of a circuit board of the present invention, illustrating a reduced degree of engagement between the conductive layers.

FIG. 14 is a top plan view of another embodiment of a circuit board of the present invention, illustrating a plurality of substantially overlapping widths between the conducting layers.

FIG. 15 is a top, plan view of another embodiment of a circuit board of the present invention, illustrating one conductive layer substantially overlapping a plurality of overlapping widths of another conductive layer.

FIG. 16 is a schematic block diagram of a power supply system of the present invention.

FIG. 17 is a schematic block diagram of an electronic circuit, such as a memory module, of the present invention.

FIG. 18 is a flow chart diagram of one embodiment of the present invention.

FIG. 19 is a flow chart diagram of an alternative embodiment of the present invention.

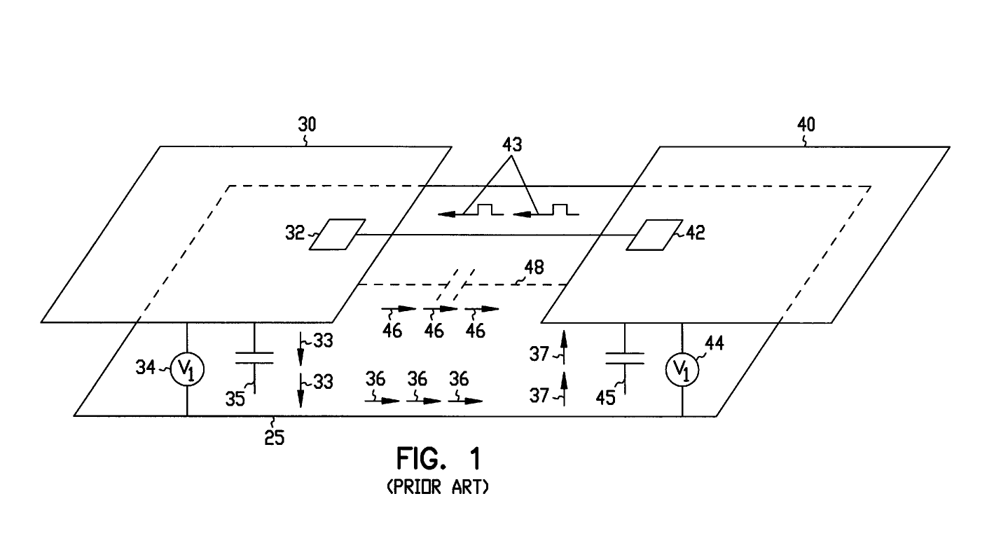

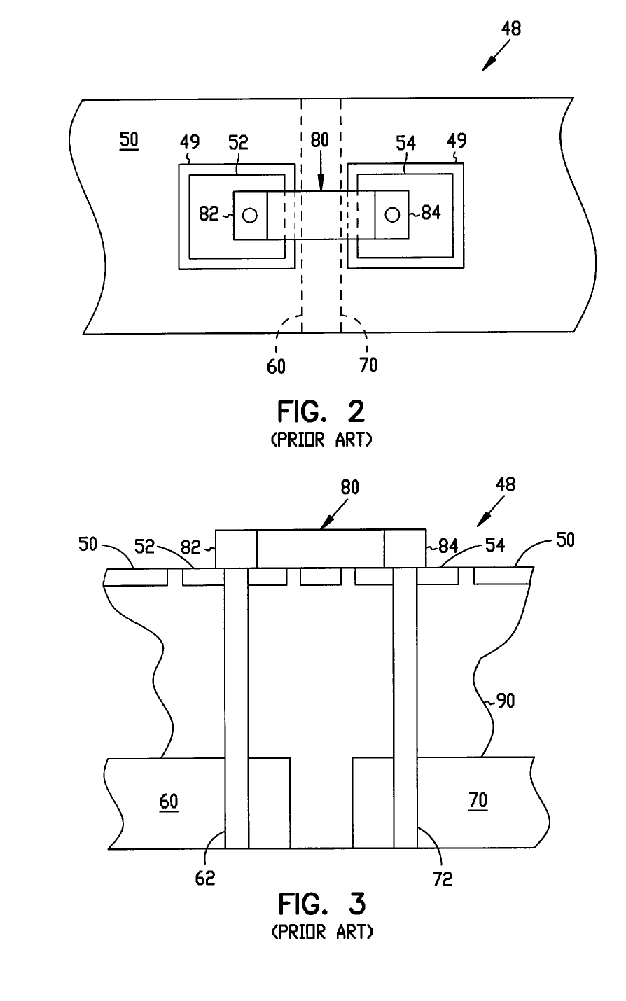

### DETAILED DESCRIPTION

The term “conductive layer” as used in the following description may be understood to include, but is not limited to, any type of conductive wiring or circuit traces used to connect circuitry mounted to printed circuit boards, such as that typically used to carry electric current, in the form of analog or digital signals, or as power, for the operational circuitry. Similarly, the term “dielectric layer” may be understood to include, but is not strictly limited to, any type of insulating material used in printed circuit boards (e.g., some type of fiber glass and epoxy resin combination) to insulate one conductive layer from another, in order to prevent shorting different conductive circuit layers together. The following detailed description is, therefore, not to be taken in a limiting sense, and the scope of the present invention is defined only by the appended claims, along with the full range of equivalents to which such claims are entitled.

According to some embodiments of the invention, a circuit board is described which includes, at a minimum, two conductive layers (either horizontally-opposed or vertically-overlapping) with a dielectric disposed between them. One of the conductive layers has formed, typically at an edge of the layer, a first interstice or other opening, which engages a second interstice formed in the other conductive layer. Alternatively, a groove may be formed in one conductive layer so as to engage a tongue formed in another conductive layer. In each case, the two conductive layers do not actually touch while they are engaged, but are separated by the dielectric layer. Thus, a capacitor is formed between the two conductive layers. It is the degree and type of engagement between the two conductive layers, as well as the type of material selected to make up the dielectric layer inserted between them, that determines the ultimate capacitance of the resulting structure.

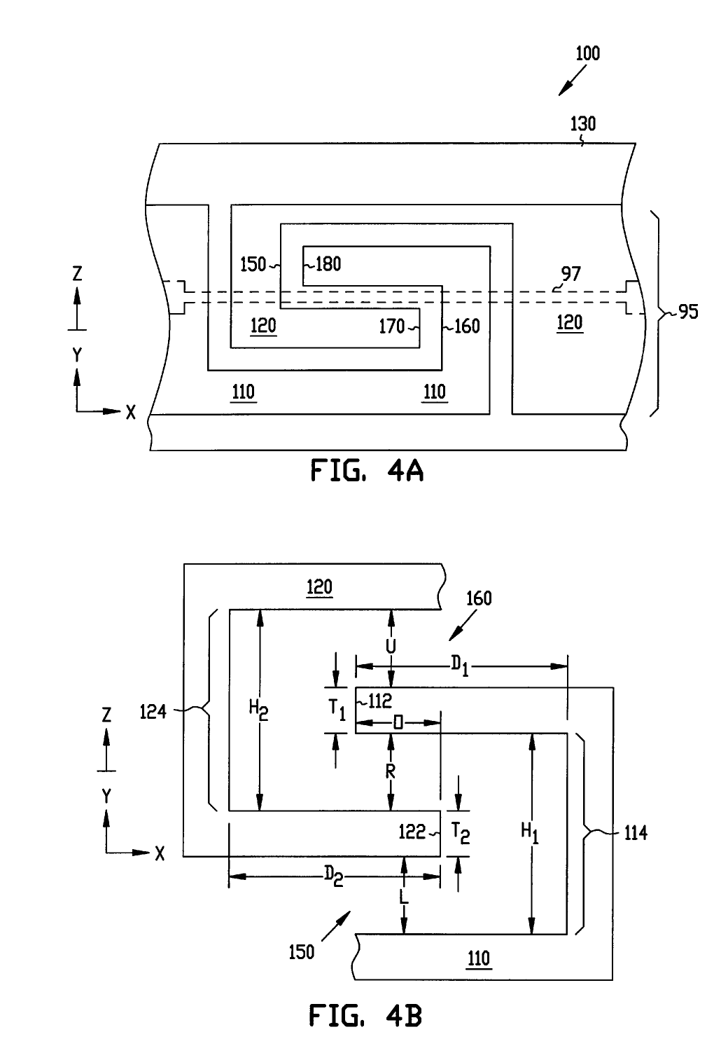

FIGS. 4A and 4B illustrate one embodiment of the novel printed circuit board 100 formed according to the teachings of the present invention. As can be seen in FIG. 4A, which is top plan (or side cut-away) view of the circuit board 100, there is a first conductive layer 1 10 having an interstice 160 formed in it. The second conductive layer 120 has a second interstice 150 formed in it. The two interstices 150, 160 are engaged, or sinuously intertwined. However, between the engaged interstices 150, 160 a dielectric layer 130 is disposed. The result is that a capacitor 95 is formed in the circuit board 100 between the first and second conductive layers 110, 120 by engaging the interstices 150, 160 across the dielectric layer 130. Whereas surface mount capacitors mounted to a circuit board using prior art techniques served to take up real estate and impede board routing, the design of the board 100 allows a capacitor 95 to be formed across which circuit traces 97 may be freely routed (on other circuit layers), since the use of a surface mount capacitor and through-hole vias are now obviated due to the capacitance thereby provided.

Several physical parameters of the circuit board 100 can be adjusted to raise or lower the effective value of the capacitor 95, formed as described above. As can be seen in more detail in FIG. 4B, each interstice 150, 160 can be characterized by a depth D1, D2, respectively, as well as a width, H1, H2, respectively. Further, each of the tongues 112, 122 engaged in the grooves 124, 114 can also be characterized by a width T1, T2, respectively (the lengths of the tongues 112, 122 are set by the depth values D1, D2 of the interstices 150, 160). Thus, each interstice 150, 160 has several dimensional elements, such as the depth, D1, D2, and the width H1, H2, which can be independently modified to suit the requirements of a particular circuit board 100 design. Similarly, the tongues 112, 122 and grooves 124, 114 also have dimensions, such as the tongue width T1, T2 and groove width/depth H2/D2, H1/D1, respectively, which can be varied to suit design requirements. In addition, the degree of overlap “O” between the first interstice 150 in the second interstice 160 can be changed by moving the grooves 114, 124 of the interstices 150, 160 closer to, or farther away from, each other. Alternatively, the degree of overlap “O” between the interstices 150, 160 can be adjusted by regulating the depths D1, D2.

Several parameters of the physical interface between the interstices 150,160, or tongue/grooves 112/124, 122/114 can also be adjusted. Again, these variations serve most directly to affect the value of capacitance measured between the conductive layers 110, 120, i.e., for the capacitor 95. For example, the separation distance “R” between the tongues 112, 122 can be adjusted. This type of adjustment will inherently affect the spacing “U” between the upper-inner wall of the interstice 160 and the outer wall of the tongue 112, as well as the spacing “L” between the lower-inner wall of the interstice 150 and the outer edge of the tongue 122. However, if such additional changes are undesired, then the thickness T1, T2 of the tongues 112, 122 may also be adjusted to compensate for the relative movement brought about by varying the separation distance “R”.

Finally, and in addition to the other modifications demonstrated above, the value of the capacitance which exists between the conductive layers 110, 120 can be adjusted by selecting the dielectric constant of the dielectric layer 130. Typically, the dielectric constant will be selected as some value between about 2 to about 11. However, given the materials commonly used in multi-layer circuit boards, the value of the dielectric constant will most probably be selected to be a value of about 3 to about 5.

Many variations exist with regard to the number of conductive layers and how they are engaged with regard to the printed circuit board 100 design of the present invention. For example, the first conductive layer 110 may be a first power plane layer of the circuit board 100. Similarly, the second conductive layer 120 may be a second power plane layer of the circuit board 100. Alternatively, the second conductive layer 120 may be a ground plane of the circuit board 100. The conductive layers are typically made of silver, gold, nickel, copper, and/or some coating mixture of tin and lead. However, any other conductive or semi-conductive material can be used to fabricate the conductive layers 110, 120. Similarly, the dielectric layer is typically selected to be a fluororesin, a polynorbornene resin, a benzocyclobutene resin, a polyimide resin, or an epoxy resin. Of course, other insulating materials (having relatively low conductance, or high resistance, such that use of the selected dielectric material would not adequately serve the function of conducting signals and/or power between the conductive layers used in the circuit board 100 design), as would be understood by those of ordinary skill in the art, may be used, such as polymers, plastics, rubbers, etc. Thus, for example, the conductive layers can be made of copper, and the dielectric from an epoxy resin.

While only the engagement of a first interstice 150 and a second interstice 160 have been described up to this point, as shown in FIG. 4A, there is no real limit to the number of interstices (or grooves and tongues) which may be engaged between the first conductive layer 110 and the second conductive layer 120.

Referring now to FIG. 5, a top plan view of another embodiment of the circuit board 100 of the present invention can be seen. In this illustration of the circuit board 100, there is shown a first interstice 150 engaged with a second interstice 160, along with a third interstice 172 engaged with a fourth interstice 174. Indeed, any number of interstices 150, 160, 172, and 174 can be engaged between the first conductive layer 110 and the second conductive layer 120. Thus, the invention may also be characterized as a first conductive layer 110, including a first plurality of interstices 160, 174, and a second conductive layer 120, including a second plurality of interstices 150, 172, wherein each one of the second plurality of interstices 150, 172 is engaged with at least one of the first plurality of interstices 160, 174. As described above, a dielectric layer 130 is disposed between the first plurality of interstices 160, 174 and the second plurality of interstices 150, 172. Also, as can easily seen in this figure, the overlap distance “O”, usually expressed as a percentage of the depth “D” of the interstices 150, 172, can be adjusted by regulating the split distance “S” between the first conductive layer 110 and the second conductive layer 120.

In most instances, the shapes of the interstices formed in the first conductive layer 110 and those formed in the second conductive layer 120 will be mirror images of each other. That is, the shape of an individual interstice 150, as shown more clearly in FIG. 4B, including the depth D1 and width H1, will roughly correspond to like dimensions (i.e., depth D2 and width H2) for the mutually-engaging interstice 160. Similarly, the shape of the grooves 124, 114 will normally be made so as to easily receive the tongues 112, 122, respectively. This type of substantial mirroring of shapes can be characterized as “complementary”. Thus, the interstices 150, 160 may be said to have a “complementary” shape, as do the tongue/groove combinations 112/124 and 122/114.

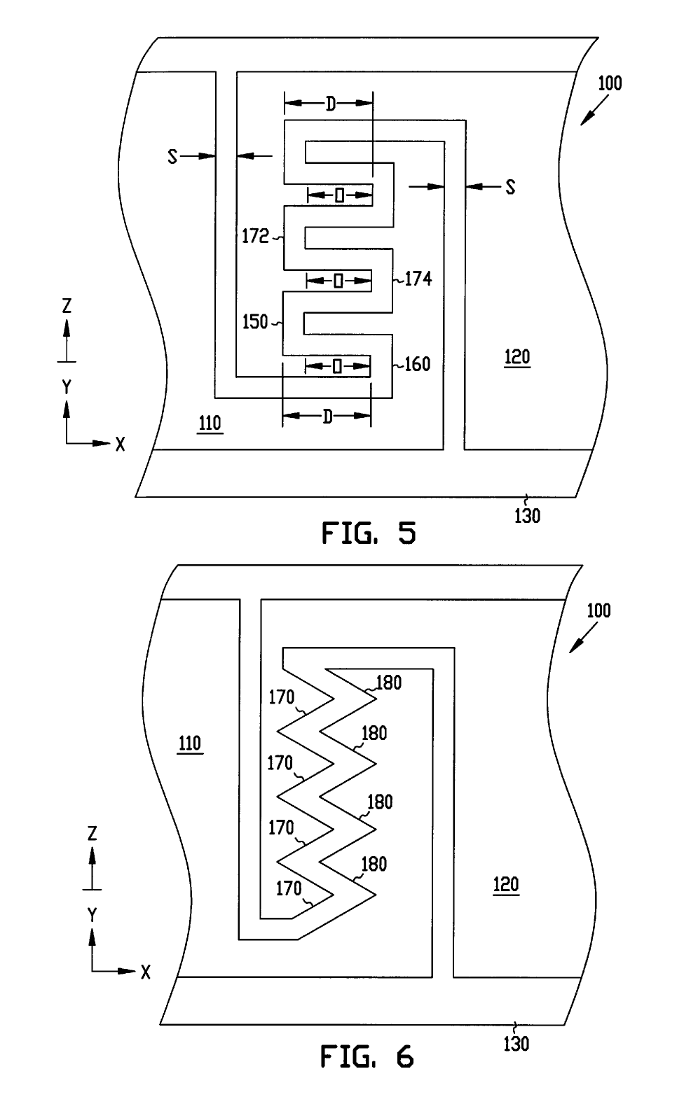

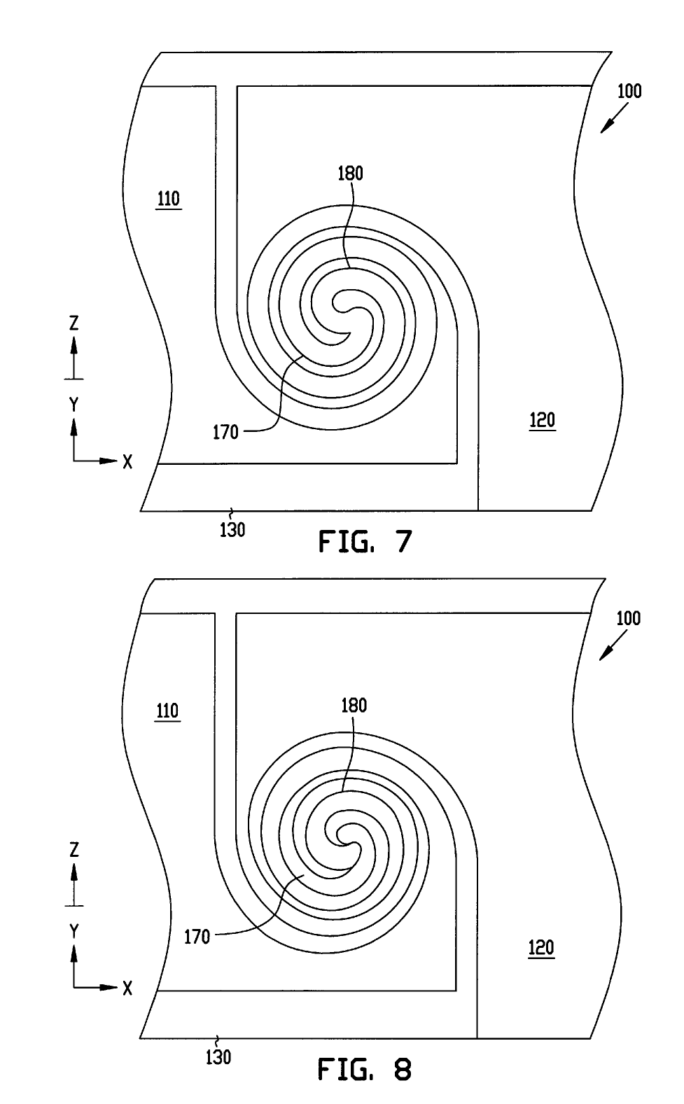

Such complementary shapes may take any number of forms. For example, as shown in FIG. 5, the interstices 150, 160 and 172, 174 may be formed into complementary rectangular shapes. As a matter of contrast, however, referring now to FIG. 6, the plurality of interstices 180 of the first conducting layer 110 may also be formed into triangular shapes. Thus, to form a complementary plurality of interstices 170 in the second conductive layer 120, the complementary engaging interstices 170 should also be formed into triangular shapes. The practically unlimited variety of shapes allowed for the interstices 150, 160, 170, 172, 174, and 180 gives designers of the circuit board 100 the freedom to specify the precise shape of engaging surfaces as the interstices are fabricated, according to the particular circuit board 100 performance desired.

For example, as mentioned previously, the performance of the circuit board 100 can vary tremendously depending on the frequency and repetition rate of various signals which propagate between layers. Depending on the signal clock speeds, signal edge rates, the inductance resident in associated operational circuitry and throughout the circuit board 100, and even the code used in a software program which may be executed by a processor and memory connected to the circuit board 100, a multitude of stray return currents, having varying wave shapes and frequencies, may arise. Such signals are typically undesirable, as they detract from the proper operation of the circuitry mounted to the circuit board 100, as well as to extraneous electromagnetic emissions.

Thus, the ability to specify and vary the shape of the physical interface between engaging interstices, or to specify the shape of the engaging tongues and grooves in accordance with the teachings of the present invention can be quite useful. In other words, a particular interstice or tongue/groove shape, and the resulting high-frequency capacitive characteristics of the engaged interstices or tongues/grooves between which the dielectric layer is disposed, can operate to pass return currents in a manner which would not otherwise be available given a fixed circuit board design configuration, along with conventionally-constructed surface mount capacitors.

Further examples of complementary shapes for interstices and tongues/grooves can be seen in FIGS. 7 and 8. In FIG. 7, the interstices have been sinuously intertwined and formed into complementary circular shapes. In this case, the thickness or width of the wall for each interstice is kept as uniform or constant as possible, given the constraints of the materials used for the conductive layers 110, 120 the material selected for the dielectric layer 130, and the circuit design implemented on the circuit board 100. Manufacturing processes may also contribute to limitations with regard to such exotic interstice engagement configurations. However, as circuit design speeds increase, and operating clock rates approach several gigahertz, the use of such complex engagement configurations may be necessary. In fact, as the present invention comes into common use, part of the circuit board design process may well involve characterizing various engagement configurations with respect to varying signal clock speeds and edge rates.

In FIG. 8, the first and second interstices of the conductive layers 110, 120 have been sinuously intertwined and formed into complementary spiral shapes. In this case, the thickness or width of the interstice walls are made to vary from relatively wide near the beginning of the spiral, narrowing down more and more so as to be relatively narrow, or even pointed, along the path of interstitial engagement, as the tops of the walls approach each other within the inter-disposed dielectric layer.

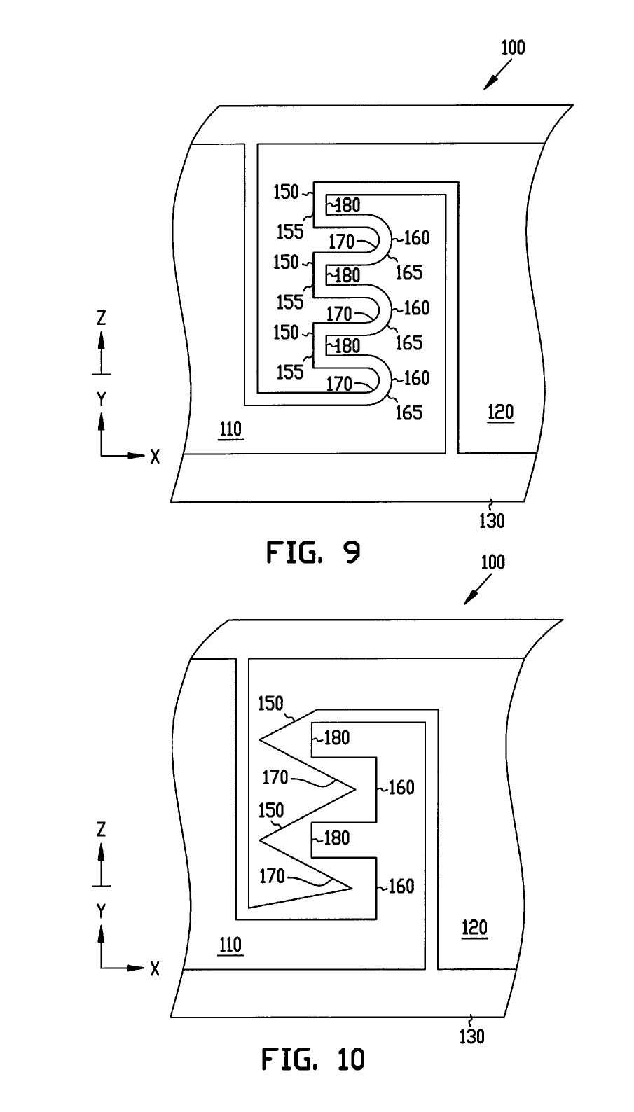

As mentioned previously, there is no ultimate limit, other than practicality (e.g. overall cost, manufacturing processes complexity, time required, etc.), to the number of interstices, or the shape of the interstices or tongues/grooves, used for engagement between the conductive layer 110 and the conductive layer 120. For example, as can be seen in FIG. 9, a plurality of grooves 165 formed in the first conductive layer 110 can be seen engaging a plurality of tongues 170 formed in the conductive layer 120. A plurality of tongues 180 is also formed in the first conductive layer 110, which overlap the tongues 170 of the second conductive layer 120, and engage the grooves 155. However, in this case, while the shape of the grooves 165 complements the shape of the tongues 170, and the shape of the grooves 155 complements the shape of the tongues 180, the shapes of the interstices 150, 160 are non-complementary, and different than any other heretofore discussed. Here some of the interstices are formed into U shapes (interstices 160), and some of the interstices are formed into box or square shapes (interstices 150). Thus, instead of characterizing the shape of the interstices 150, 160 with any particular dimensions, or ratios of dimensions (e.g., the depth D1 is twice as deep as the width H1, or the tongue thickness T1 is one-third of the width H1), it may also be useful to characterize the shape of individual interstices as that of commonly known geometric shapes or alphabetic characters, such as U shaped, triangular shaped, square shaped, elliptically or oval shaped, etc.

Turning now to FIG. 10, yet another embodiment of the multi-layer circuit board 100 of the present invention, in a top plan view, can be seen. In this case, multiple, non-complementary engaging interstices can be seen. More particularly, the first plurality of interstices 160 formed in the first conducting layer 110 are shaped in the form of rectangles, while the second plurality of interstices 150, formed in the second conductive layer 120, are shaped in the form of triangles. Another way of characterizing the component elements is by saying that the triangular shaped tongues 170 are engaged with the rectangular shaped grooves 160, or that the rectangular shaped tongues 180 are engaged with the triangular shaped grooves 150. Again, there is no limit, other than practicality with regard to manufacturing processes, materials, and performance characteristics, which need be applied to the number and/or shape of the mutually-engaging interstices and/or tongues/grooves.

Up to this point, and as mentioned above, the conductive layers of the circuit board 100 have been described as being arranged in a horizontally-opposed fashion, which includes conductive layers arranged apart from each other and laying with the dimensions of length and width in a substantially horizontal (X-Y) plane. The depth of such horizontally-opposed conductive layers is usually only a small fraction of the width and length of the associated circuit board. However, as was briefly mentioned above, the conductive layers can also be arranged or stacked in a vertically-overlapping fashion, one on top of the other. In each case, the dielectric layer is disposed between the conductive layers. The term “disposed between” means that the dielectric layer is typically used as a supporting surface to space apart the conductive layers when they are horizontally-opposed and formed on a surface of the dielectric material (so that the conductive layers do not make physical contact with each other). The term “disposed between” may also mean that the dielectric material is inserted, injected, or sandwiched in between the conductive layers when the conductive layers are vertically-overlapping (again, to prevent physical contact between the conductive layers)

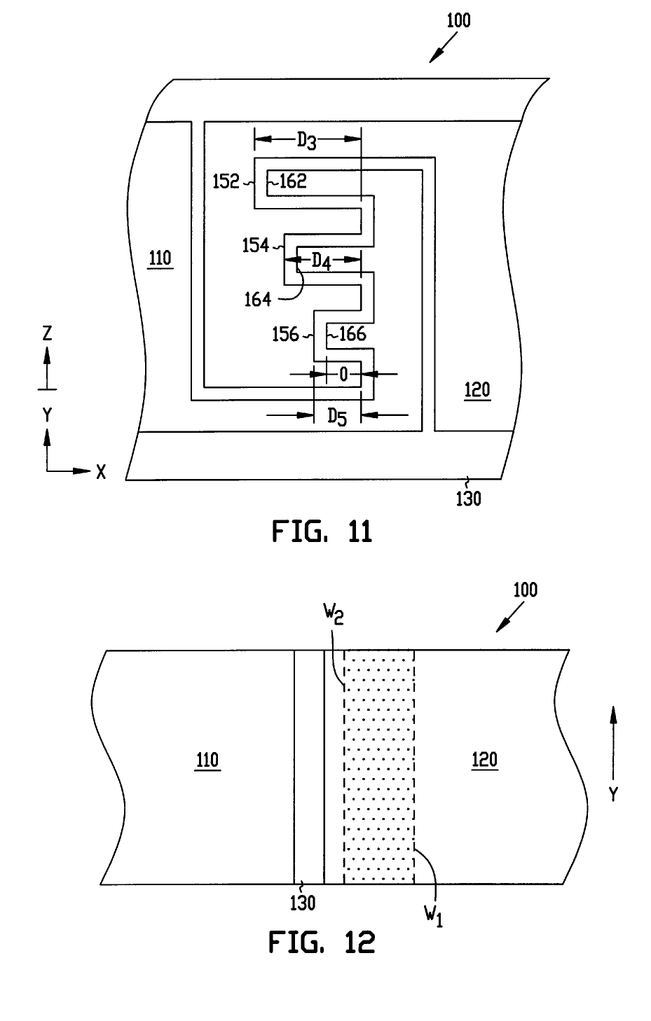

Referring back to FIGS. 4-10, which have heretofore been described as top, plan views of the invention (using the “X” and “Y” directions to define a substantially horizontal, planar coordinate system in which the conductive layers of the circuit are disposed), it should also be understood that FIGS. 4-10 can be alternatively be considered as side, cut-away views of the invention (using the “Z” direction to define a vertical dimension, or depth, which is substantially perpendicular to the horizontal X-Y plane in which the circuit board lays). Thus, it should now be noted that any of the FIGS. 4-10, along with FIGS. 11, 13, 16, and 17 may represent either a top, plan view, or a side, cut-away view of the invention

Turning now to FIG. 11, a vertically-overlapping (or horizontally-opposed) plurality of mutually engaging, complementary, graded depth rectangular interstices can be seen. More particularly, the first conductive layer 120 includes a first groove 152, a second groove 154, and a third groove 156. The second conductive layer 110 includes a first tongue 162 (engaged with the first groove 152), a second tongue 164 (engaged with the second groove 154), and a third tongue 166 (engaged with the third groove 156). The depths of the first, second, and third grooves, D3, D4, and D5, respectively are all different, and chosen such that D3>D4>D5, to produce the graded effect shown in FIG. 11. Although the lengths of the first, second, and third tongues 162, 164, and 166 are also shown in FIG. 11 to be graded in a complementary fashion, they are not explicitly listed in the drawing for clarity. However, it should be noted that, as described above, the amount of overlap by the tongues 162, 164, and 166 with their respective grooves 152, 154, and 156 (denoted as “O” in other Figures) can be varied in this particular case also. While the amount of tongue overlap along the lengths of the grooves is typically selected to be from about 5 percent to about 99 percent, it is almost always more than about 5 percent, for at least one of the tongue/groove combinations. This degree of overlap, denoted by the dimension “O”, and usually expressed as a percentage of the depths D3, D4, and/or D5 is also typical of all the other configurations shown, and heretofore described.

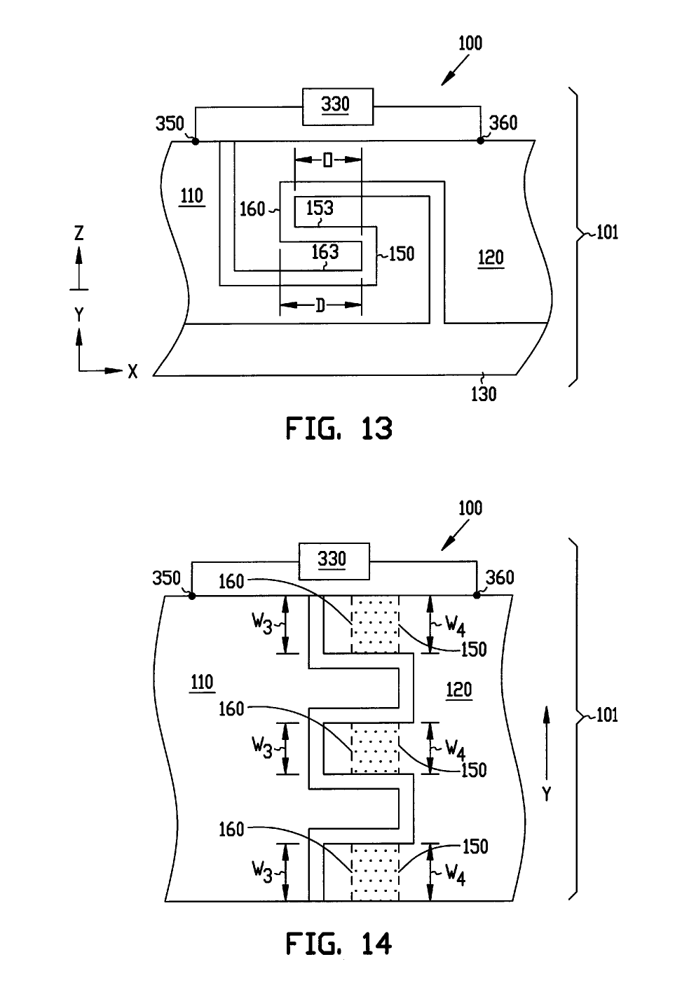

Referring now to FIGS. 12 and 13, yet another embodiment of the circuit board 100 can be seen. In this case, FIG. 12 is a top, plan view of a multi-layer circuit board 100, and FIG. 13 may be viewed as a side, cut-away view illustrating substantially overlapping widths between the conductive layers 110 and 120. The first interstice 150 is characterized by a single width W1, laying in a first plane parallel to the conductive layer 110. Similarly, the second interstice 160 is characterized by a single width W2, laying in a second plane parallel to the conductive layer 120. The edges of these planes (first plane edge 153 and second plane edge 163 shown in FIG. 13) are substantially parallel to each other and to the upper surfaces of the conductive layers 110, 120 shown in FIG. 12, and perpendicular to the cutting plane used to section the conductive layers 110, 120, and the dielectric layer 130, in FIG. 13 (assuming that FIG. 13 is taken to be a side, cut-away view). For simplicity, the widths W1 and W2 are shown in FIG. 12 to be substantially overlapping in the “Y” direction. The greater the degree of overlap in the Y direction, and the greater the degree of overlap “O” between the interstices 150, 160, measured as a percentage of the distance “D”, the larger the value of the capacitance which can be formed between the conductive layers 110 and 120. Thus, the widths W1 and W2 will be positioned in a substantially overlapping fashion, as shown here, in most designs, but there is no absolute requirement that this be so.

An electronic circuit 101, constructed according to the teachings of the present invention, can be seen in FIG. 13. Assuming a side, cut-away view, the edges of the planes 153 and 163 are clearly shown, being substantially parallel to each other and perpendicular to the cutting plane used to section the conductive layers 110 and 120 and the dielectric layer 130. In this case, a first power terminal 350 of a memory module or processor 330 is operationally connected to the first conductive layer 110, which has a first interstice 150. A second power terminal 360 of the memory module or processor 330 is likewise operationally connected to the second conductive layer 120, which has a second interstice 160. The first interstice 150 is engaged or sinuously intertwined with the second interstice, and the dielectric layer 130 is disposed between the engaged interstices 150, 160. In most instances, designers will choose to form the capacitance between the conductive layers 110, 120 as close to the power terminal 350, 360 connections as is reasonably possible. In this way, stray return currents may be reduced or eliminated without resorting to the placement of extra capacitance on the board 100 in the form of traditionally-applied surface mounted bypass capacitors.

Keeping in mind the foregoing description, reference is now made to FIG. 14, wherein is shown a top, plan view of another embodiment of the circuit 101 according to the teachings of the present invention. In this case, the first interstice 150 has a plurality of first widths W3 laying in the first plane. The second interstice 160 has a complementary plurality of second widths W4 laying in the second plane. It should be noted that the side view of the configuration illustrated in FIG. 14 is identical to that shown in FIG. 13, such that the edges of the first and second planes 153 and 163 are substantially parallel with each other. However, in this case, each one of the first plurality of widths W3 substantially overlaps at least one of the second plurality of widths W4. Thus, in this manner, a multiplicity of vertically-overlapping capacitors, or capacitances, may be formed into the circuit board 100 to which the integrated circuit, memory module, or processor 330 is connected so as to form the circuit 101. Again, as described above, the widths W3 and W4 are shown to be substantially overlapping. This provides the greatest amount of capacitance per unit area of the combined surfaces of the conductive layers 110 and 120. While the plurality of widths W3 and W4 are shown to be roughly similar in size in FIG. 14, there is no absolute requirement that this be so. In fact, the designer of the circuit board 100 may select widths W3 and W4 to be any size that serves the purposes of a particular design according to the performance requirements of the circuit 101. It should be noted that, while FIG. 14 shows a plurality of vertically-overlapping capacitors formed into the circuit board 100, the invention also includes forming a plurality of horizontally-opposed capacitors in the circuit board 100.

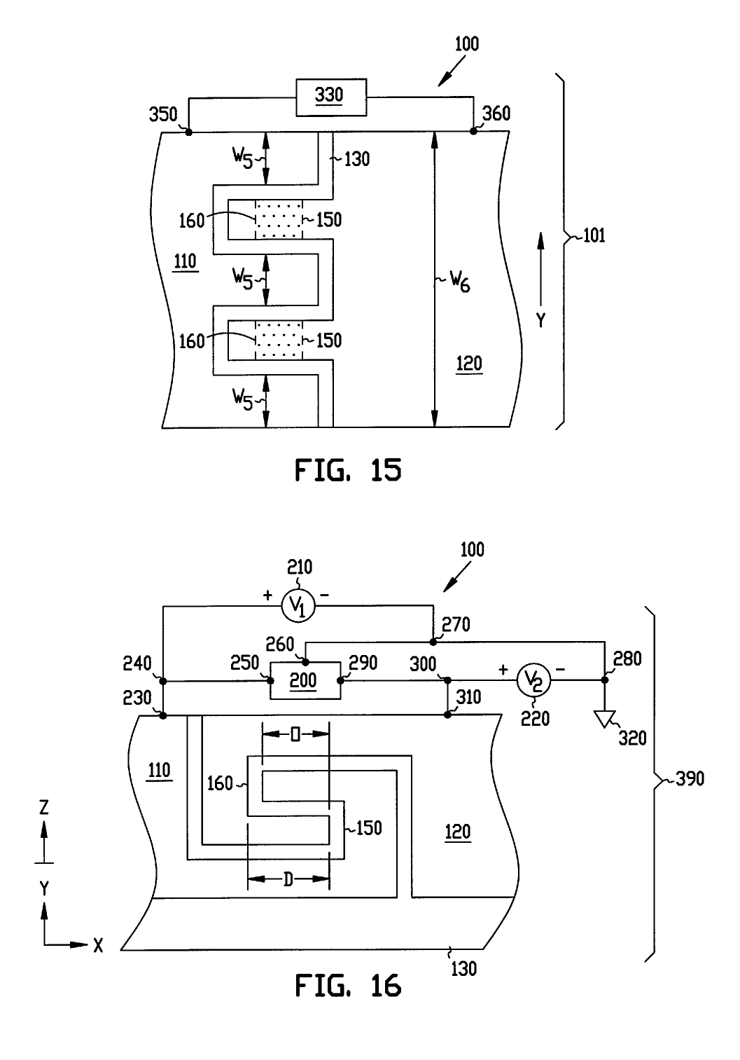

In a similar vein, reference is now made to FIG. 15, wherein a top, plan view of a circuit 101 constructed according to the teachings of the present invention is shown. In this case, the first interstice 150 has a plurality of first widths W5 laying in the first plane. However, the second interstice 160 has only a single width W6 laying in the second plane. Thus the width W6 is shown to substantially overlap at least one (and in this particular instance, all) of the plurality of widths provided by the first interstice 150. Again, as noted above, the first and second planes are substantially parallel to each other, as shown in the side view of this configuration (see FIG. 13, taken as a side, cut-away view). Also, as is noted above, while the plurality of widths W5 are shown to be each substantially overlapped by the single width W6 along the “Y” direction, there is no absolute requirement that this be so. The number and size of the widths W5 may be reduced or increased, as may be the size of the single width W6, according to the inclination of the circuit board 100 designer.

Turning now to FIG. 16, a power supply system 390 constructed according to the teachings of the present invention is shown. In this case, a first power supply 210 having a first power terminal 240 and a first ground terminal 270 is operationally connected to the first conductive layer 110 of the circuit board 100 at node 230, using the first power terminal 240. As described above, the first conductive layer 110 has been formed into a first interstice 150.

The power supply system 390 also includes a second power supply 220 having a second power terminal 300 and a second ground terminal 280. The second power supply 220 is also operationally connected to the circuit board 100. In this case, the second power terminal 300 of the second power supply 220 is connected to node 310 of the second conductive layer 120. As described previously, the second conductive layer 120 has also been formed into a second interstice 160. In this figure, the first ground terminal 270 and the second ground terminal 280 are connected together, as well as to a signal ground 320, which typically resides on another conductive layer of the circuit board 100 (not shown, but well known to those of ordinary skill in the art).

A memory circuit module, integrated circuit, or processor 200 having a first supply terminal 250 (e.g., +3.3V) may also be connected to be first power terminal 240 of the first power supply 210, and a second supply terminal 290 (e.g., +2.5V), may be connected to the second power terminal 300 of the second power supply 220. According to conventional practice, the ground terminal 260 of the memory circuit module, integrated circuit, or processor 200 is connected to the ground layer or plane 320, along with the first and second ground terminals 270, 280 of the first and second power supplies 210 and 220. Again, the dielectric layer 130 is disposed between the first interstice 150 and the second interstice 160, such that the dielectric constant of the dielectric layer may be selected to introduce a predetermined amount of capacitance between the sinuously intertwined conductive layers 110 and 120.

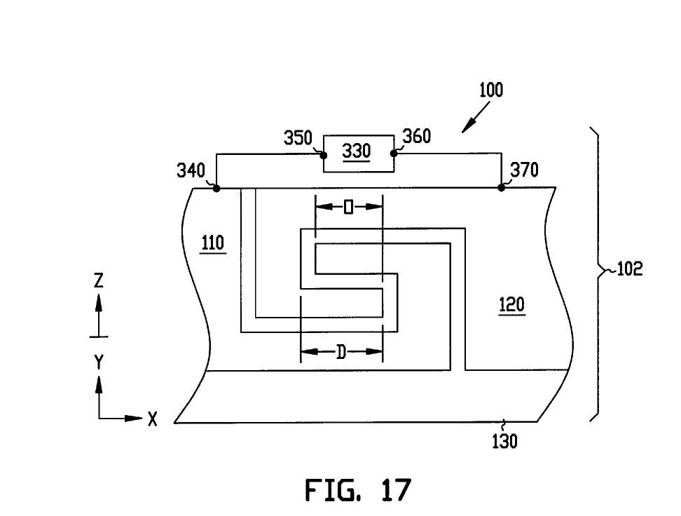

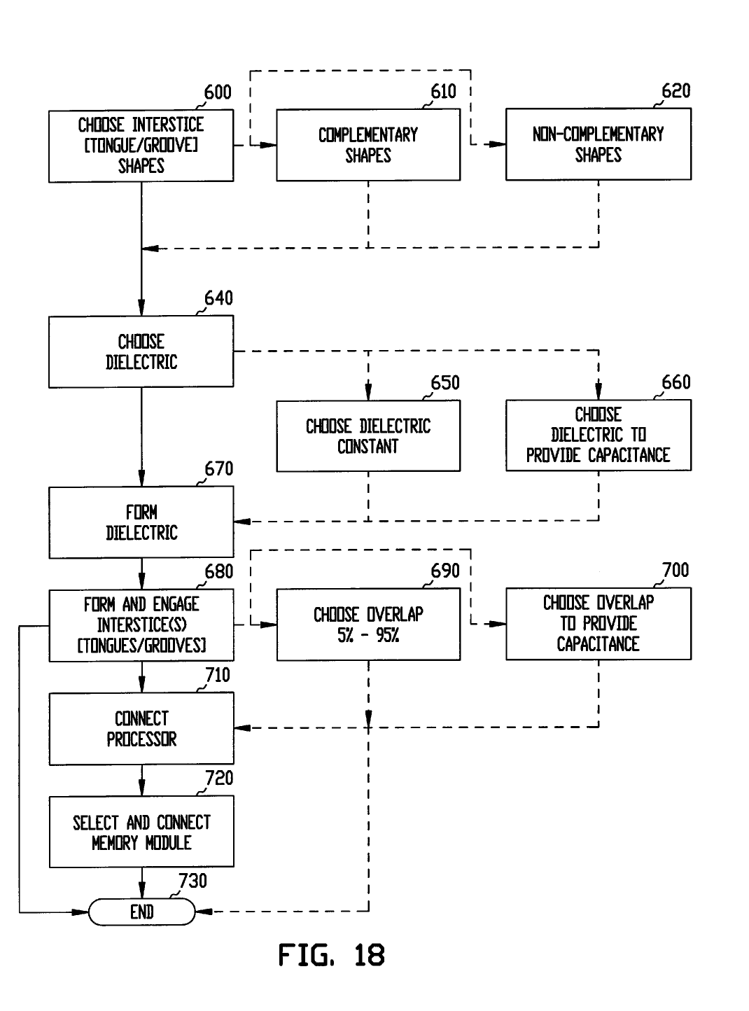

Reference is now made to FIG. 17, wherein is shown a schematic block diagram of another electronic circuit 102 constructed according to the teachings the present invention. In this case, a memory circuit module 102 is fabricated by taking the power terminal 350 of a memory chip or integrated circuit 330 and connecting it to the first conductive layer 110 at a node 340. Similarly, the memory chip or integrated circuit 330 can be connected to the second conductive layer 120 (e.g. a ground plane) at a node 370, using a ground terminal 360. According to the teachings of the invention, the capacitance between the conductive layers 110,120 can easily be adjusted by selecting a particular amount of overlap “O” (typically expressed as a percentage of the depth “D”). Further, the dielectric layer 130 material may be selected to have a dielectric constant of about 2 to about 11 to adjust the capacitance between the conductive layers 110, 120. However, as mentioned previously, the dielectric constant will most likely be selected to be about 3 to about 5, if commonly available materials are used.

In a similar fashion, a computer system 102 can be fabricated by taking the power terminal 350 of a processor or central processing unit 330 and connecting it to the first conductive layer 110 at a node 340. Likewise, the processor or central processing unit 330 can also be connected to the second conductive layer 120 (e.g. a ground plane) at a node 370, using a ground terminal 360. Then, according to the teachings of the present invention, and as determined by the circuit board 100 designer, the capacitance between the conductive layers 110,120 can easily be adjusted as previously described.

It will be understood by those of ordinary skill in the art that the embodiments shown in FIGS. 13-17 illustrate electronic systems, circuitry, and modules in which the novel circuit board of the present invention, having mutually-engaged or sinuously intertwined interstices, or mutually-engaged tongues/grooves, including the capacitance formed therein, are included. Thus, one of ordinary skill in the art will understand upon reading this description that the circuit board of the present invention can be used in applications other than for memory modules, processors, power supply systems, and various other forms of circuitry and systems, and thus, the invention is not to be so limited. The illustrations of an electronic circuit 101, as shown in FIGS. 13-15, the electronic system 390 shown in FIG. 16, and the electronic system/module 102 shown in FIG. 17 are intended to provide a general understanding of a few of the applications which may be served by the structure and circuitry of the present invention, and are not intended to serve as a complete description of all the elements and features of electronic circuitry, modules, or systems which make use of the novel circuit board structure described herein.

Applications which may include the novel circuit board of the present invention as described in this disclosure include electronic circuitry used in high-speed computers, arrays of memory modules and other circuit cards, device drivers, power modules, communication circuitry, modems, processor modules, power supply systems, memory integrated circuits, embedded processors, and application-specific modules, including multilayer, multi-chip modules. Such circuitry may further be included as sub-components within a variety of electronic systems, such as clocks, televisions, cellular telephones, personal computers, printers, automobiles, industrial control systems, aircraft, and others.

FIGS. 4A, 4B, and 5-17 presented and described in detail above are similarly useful in describing various methods which may be embodied by the teachings of the present invention. Those of ordinary skill in the art will realize that various elements of the circuits, systems, modules, and circuit boards of the present invention may be assembled in accordance with the structures described in the various figures. However, for clarity, an additional and more particular embodiment of one method of forming a circuit board according to the teachings of the present invention is illustrated in flow chart form in FIG. 18.

This first method of fabricating a circuit board according to the teachings of the present invention, generally directed toward a horizontally-opposed arrangement of conductive layers, may begin at block 600 with choosing the shapes of the interstices in the first conductive layer and the second conductive layer. As described previously, these may be any number of shapes, including rectangular, triangular, circular, spiral, elliptical, square, etc. Alternatively, block 600 includes the possibility of choosing tongue and groove shapes for engaging with each other on either side of the dielectric layer, in a horizontally-opposed, or vertically-overlapping. In either case, the circuit board designer may decide to use complementary shapes according to block 610, or non-complementary shapes, according to block 620. Considerations such as cost, number of board layers, circuit clocking speeds, edge rates, inductance, etc. may dictate the best course to choose; experience in this area as circuit design clock speeds increase will probably provide the best determination.

At this time, the dielectric layer material is usually chosen and formed to support horizontally-opposed conductive layers, according to block 670. Thus, prior to forming the dielectric layer, the dielectric constant for the dielectric layer may be chosen in block 650. As mentioned above, the dielectric constant is typically selected to be about 3 to about 5, considering conventional materials, but may be selected from any value from about 2 to about 11 in most industrial situations. As may be apparent to those of ordinary skill in the art, more exotic dielectric layer materials may also be selected to provide dielectric constant values considerably outside of the ranges mentioned herein (i.e., less than about 2, or greater than about 11).

In accordance with block 660, the dielectric constant may also be chosen to provide a preselected amount of capacitance, or a maximum amount of capacitance, between the first and second conductive layers. Thus, considering the distance between the interstices of the layers, or the tongues/grooves, the amount of overlap between them (see blocks 690 and 700), and the thickness of the conductive and dielectric layers, each may influence the selection of a particular dielectric layer material and/or dielectric constant as the circuit board is fabricated.

After forming the dielectric layer in block 670, the first and second sets of interstices or grooves and tongues (included in the first and second conductive layers, respectively) are formed and engaged, or sinuously intertwined, in accordance with block 680 of the method. That is, the first and second conductive layers are formed on the dielectric layer, and then the interstices may be formed in the conductive layers. Thus, this part of the procedure may also include forming the first interstice, or first plurality of interstices, in the first conductive layer. If the tongue and groove approach is taken, then one or more grooves can be formed in the conductive layer. At this time, not only is the shape of the first set of interstices or grooves determined, but the size of these elements (e.g., depth and width) is also defined. The factors which determine the shape and size will usually include considerations such as the dielectric constant of the dielectric layer, the amount of capacitance desired between the conductive layers, as well as the spacing between the conductive layers and the shape of the engaging interstices or grooves/tongues.

At this time, although not necessarily simultaneously, the second interstice, or second plurality of interstices, can be formed. If the tongue and groove approach is taken, then one or more tongues can now be formed in the second conductive layer. In either case, the second set of interstices or tongues will be formed according to the shapes chosen in block 600, and whether complementary shapes where chosen (block 610) or non-complementary shapes were chosen (block 620). The size of the second set of interstices, or the tongues, will usually be determined by the size of the first set of interstices, or grooves, along with the materials selected for the first and second conductive layers, and the dielectric layer (see block 670).

The amount the first interstice is overlapped by the second interstice may also be selected, in accordance with block 690, and is usually chosen to be from about 5 percent to about 99 percent of the depth of the most shallow interstice. Similarly, if the tongue and groove approach is taken, the overlap of the depth of the most shallow groove by its corresponding, engaging tongue is typically chosen to be at least about 5 percent, and up to about 99 percent of the depth of the groove. In certain circumstances, however, the circuit board designer may decide to engage corresponding interstices and/or tongues and grooves by an amount of less than about 5 percent.

In accordance with block 700, the degree or amount of overlap between one or more sets of interstices may also be chosen to provide a preselected amount of capacitance (or maximum amount of capacitance) between the first and second conductive layers. This part of the method may be used to provide a fine adjustment of the capacitance between the layers, in addition to that provided by selecting a particular dielectric constant, or to adjust for dielectric materials of inconsistent or highly variable dielectric constants, or even to provide localized areas of greater or lesser capacitance for a circuit board design in order to accommodate varying signal speeds and characteristics which may arise in different locations of the board.

By following this procedure, as shown in FIG. 18, a circuit board formed in accordance with the teachings of the present invention may be fabricated by those of ordinary skill in the art. However, to assemble a computer system according to the teachings of the present invention, more is required. For example, the board can be made to include a processor or central processing unit by connecting one to the board in block 710. Then a memory module can be selected and connected to the circuit board to complete the system, which now includes a memory module and processor, using the novel circuit board of the present invention. This embodiment of a method for forming a circuit board and computer system according to the teachings of the present invention ends at block 730.

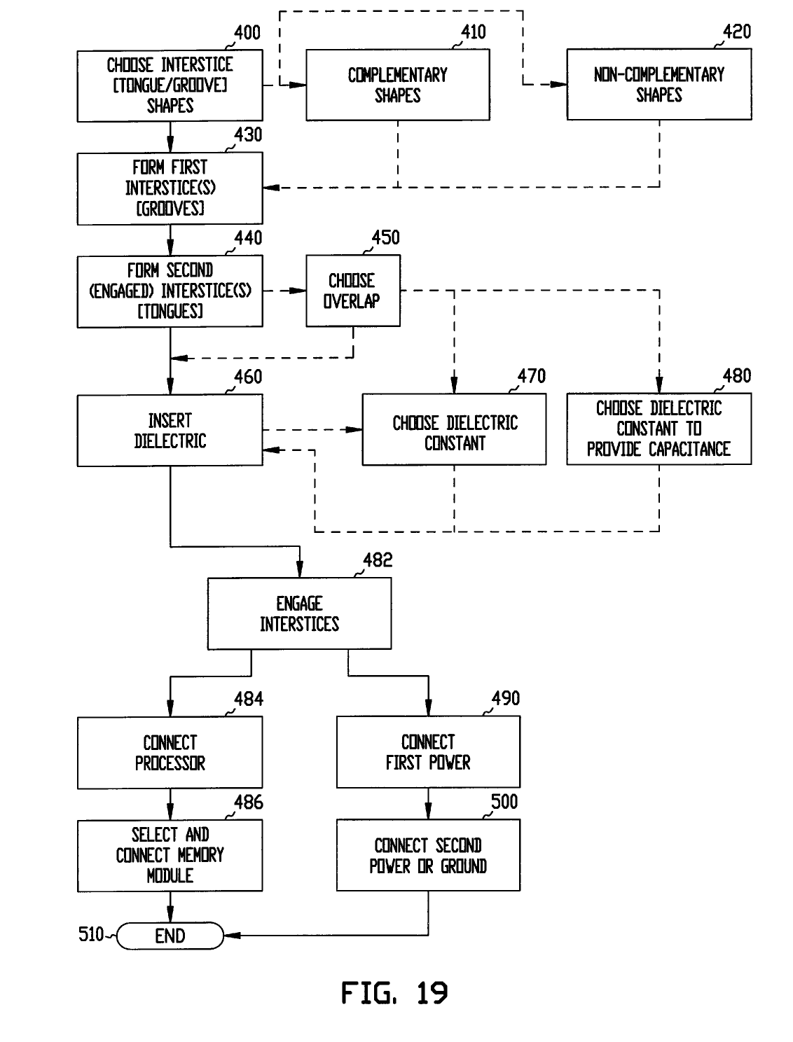

Turning now to FIG. 19, another method of fabricating a circuit board according to the teachings of the present invention, generally directed toward a vertically-overlapping arrangement of the conductive layers, can be seen. This embodiment of the invention begins at block 400 with choosing the shapes of the interstices in the first conductive layer and the second conductive layer. As described previously, these may be chosen as any number shapes, including U-shaped, rectangular, triangular, circular, spiral, elliptical, square, etc. Alternatively, block 400 includes the possibility of choosing tongue and groove shapes for engaging or sinuously intertwining with each other as the dielectric layer is disposed between them. In either case, the circuit board designer may decide to use complementary shapes according to block 410, or non-complementary shapes, according to block 420. As described above, such non-complementary combinations may include rectangles and triangles. Engagement may even occur using alternating complementary shapes, such as those illustrated in FIG. 9. Again, considerations such as circuit processing speeds, clock edge rates, pre-existing and newly introduced inductances and capacitances all will provide some guidance as to the best course to choose, as will the experience of the circuit board designer.

The next part of the procedure, shown in block 430, involves formation of the first interstice, or first plurality of interstices, in the first conductive layer. If the tongue and groove approach is taken, then the first groove, or set of grooves can be formed in the first conductive layer. As before, at this time, not only is the shape of the first set of interstices or grooves determined, but the size of these elements (e.g., depth and width) is also chosen. The factors which determine the shape and size will typically include considerations such as the dielectric constant of the dielectric layer, the desired filtering behavior of the formed capacitance, as well as the amount of ringing produced by the interface between the conductive layers, as determined by the spacing between the conductive layers and the shape of the engaging interstices or grooves and tongues interacting with high-speed return currents.

After the first set of interstices or grooves are formed in block 430, the second interstice, or second plurality of interstices can be formed (and if desired at this time, engaged with the first interstice, or first plurality of interstices), according to block 440. If the tongue and groove approach is taken, then one or more tongues can now be formed in the second conductive layer, so as to engage the corresponding grooves in the first conductive layer. In either case, the second set of interstices or tongues will be formed according to the shapes chosen in block 400, and whether complementary shapes were chosen (block 410) or non-complementary shapes were chosen (block 420). The size of the second set of interstices, or the tongues formed in the second conductive layer will usually be determined by the size of the first set of interstices, or grooves, formed in the first conductive layer in accordance with block 430, along with the materials selected for the first and second conductive layers, and the dielectric layer (see blocks 470 and 480).

At the time the first and second sets of interstices or grooves and tongues (included in the first and second conductive layers, respectively) are engaged, or sinuously intertwined, in accordance with block 440, the amount the first interstice is overlapped by the second interstices can be chosen in block 450 to be from about 5 percent to about 99 percent of the depth of the most shallow interstice. Similarly, if the tongue and groove approach is taken, the overlap of the depth of the most shallow groove by its corresponding, engaging tongue is typically chosen to be at least about 5 percent, and up to about 99 percent of the depth of the groove. In certain circumstances, however, as mentioned above, the circuit board designer may decide to engage corresponding interstices and/or tongues and grooves by an amount of less than about 5 percent. Again, the degree or amount of overlap between one or more sets of interstices may also be chosen to provide a preselected amount of capacitance between the first and second conductive layers.

Block 450 may be used to provide a fine adjustment of the capacitance between the conductive layers, in addition to that provided by selecting a particular dielectric constant, or to adjust for dielectric materials of inconsistent or highly variable dielectric constants, or to provide localized areas of greater or lesser capacitance for a circuit board design to accommodate varying signal speeds and characteristics which may arise in different locations of the board.

At this time, the dielectric layer is inserted between the conductive layers according to block 460. However, prior to inserting the dielectric layer between the conductive layers, the dielectric constant for the dielectric layer may be chosen in block 470, after executing the procedures in blocks 440 and/or 450. As mentioned above, the dielectric constant is typically selected to be about 3 to about 5, but may be selected from any value from about 2 to about 11 in common industrial situations. Other dielectric layer materials may also be selected to provide dielectric constant values considerably outside of the ranges mentioned herein (i.e., less than about 2, or greater than about 11).

The dielectric constant may also be chosen to provide a preselected amount of capacitance between the first and second conductive layers, in accordance with block 480. Thus, considering the distance between the respectively engaged interstices, or the tongues and grooves, the amount of overlap between them (refer to block 450), and the thickness of the respective conductive and dielectric layers each may influence the selection of a particular dielectric layer material and/or dielectric constant as the circuit board is fabricated.

If the interstices of the conductive layers have not been engaged up to this point (i.e., the dielectric was merely inserted between the non-engaged conductive layers in step 460), then the interstices of the conductive layers can be engaged or sinuously intertwined in block 482.

By following this procedure, as shown in FIG. 19, a circuit board formed in accordance with the teachings of the present invention may be fabricated by those of ordinary skill in the art. However, to assemble a circuit module, using a memory chip and a circuit board, for example, or to assemble a computer system, according to the teachings of the present invention, more is required. Thus, the first conductive layer or power plane of the board can be connected to a power terminal of the memory chip in block 490. The second power terminal of the memory chip, or a ground terminal of the memory chip can then be connected to the second conducting layer (a second power plane or ground plane) of the circuit board in block 500, which completes the circuit module. This embodiment of a method for forming a circuit board and circuit module according to the teachings of the present invention ends at block 510. In addition, or alternatively, the board can be made to include a processor or central processing unit by connecting one to the board in block 484. Then a memory module can be selected and connected to the circuit board to complete the system in block 486, which now includes a memory module and processor, using the novel circuit board of the present invention. This embodiment of a method for forming a circuit board and computer system according to the teachings of the present invention also ends at block 510.

Although not heretofore explicitly mentioned, the circuit board of the present invention may also be formed by engaging sets of interstices and sets of tongues/grooves simultaneously. In other words, the first conductive layer may comprise one or more interstices, along with one or more grooves. The second conductive layer may comprise, in turn, one or more mutually-engaging interstices, and one or more mutually-engaging tongues. These may be engaged or sinuously intertwined at the same time, after insertion of the dielectric layer. Other processes to form the circuit board of the present invention, or a capacitor embodied by a circuit board according to the teachings of the present invention, wherein a dielectric layer is injected or otherwise disposed between the conducting layers of the circuit board, as occurs in various polymer and plastic blow-molding and shaping procedures may also be practiced by those of ordinary skill in the art.

### CONCLUSION

Thus, various embodiments of the invention may provide a novel circuit board, which can be incorporated into electronic circuits, modules, and systems, and methods for forming and connecting such circuit boards, circuits, modules, and systems. The novel circuit board can provide a mechanism whereby controlled amounts of capacitance can be introduced into the structure of circuit boards by using engaged or sinuously intertwined interstices and tongues/grooves which are separated by a selected dielectric material, such that the conductive layers are horizontally-opposed, or vertically-overlapping. According to some of the embodiments, the need for surface mounted capacitors is significantly reduced, or eliminated, making way for greater numbers of vias between circuit board layers, and an increased variety of circuitry which can be supported within a limited area, due to the increased circuit routing pathways which are made available. The result is the addition of a capacitive component, or multiplicity of such components, without unduly burdening the design of high-speed circuitry mounted to multi-layer circuit boards.

The accompanying drawings that form a part hereof show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

What is claimed is:

1. A circuit board, comprising:
a first conductive layer including a first interstice and a third interstice;
a second conductive layer including a second interstice engaged with the first interstice, and a fourth interstice engaged with the third interstice; and
a dielectric layer disposed between the first and third interstices, and the second and fourth interstices.

2. The circuit board of claim 1, wherein the first and second interstices are formed in a first complementary shape.

3. The circuit board of claim 2, wherein the third and fourth interstices are formed in a second complementary shape.

4. The circuit board of claim 1, wherein the first and second interstices are formed in a complementary rectangular shape.

5. The circuit board of claim 4, wherein the third and fourth interstices are formed in the complementary rectangular shape.

6. The circuit board of claim 1, wherein the first and second interstices are formed in first non-complementary shape.

7. The circuit board of claim 6, wherein the third and fourth intertices are formed in a complementary shape.

8. The circuit board of claim 6, wherein the third and fourth interstices are formed in a second non-complementary shape.

9. The circuit board of claim 1, wherein the first conductive layer includes a plurality of grooves, and wherein the second conductive layer includes a plurality of tongues.

10. The circuit board of claim 9, wherein each one of the plurality of grooves includes an increasing depth, and wherein each one of the plurality of tongues includes a complementary increasing length.

11. The circuit board of claim 1, wherein the first interstice has a plurality widths laying in a first plane, and wherein the second interstice has a single second width laying in a second plane.

12. A circuit board, comprising:
a first conductive layer sinuously intertwined with a second conductive layer; and
a dielectric layer disposed between the first conductive layer and the second conductive layer, wherein the first and second conductive layers are formed in a complementary spiral shape.

13. The circuit board of claim 12, wherein the dielectric layer has a dielectric constant of about 2 to about 11.

14. The circuit board of claim 12, wherein the dielectric layer is selected from a group consisting of fluororesins, polynorbomene resins, benzocyclobutene resins, polyimide resins, and epoxy resins.

15. The circuit board of claim 12, wherein a degree of overlap between the first and second conductive layers is chosen to provide a preselected amount of capacitance.

16. A circuit board, comprising:
a first conductive layer sinuously intertwined with a second conductive layer; and
a dielectric layer disposed between the first conductive layer and the second conductive layer, wherein the first and second conductive layers are formed in a complementary circular shape.

17. The circuit board of claim 16, wherein a degree of overlap between the first and second conductive layers is chosen to provide a preselected amount of capacitance.

18. A circuit board, comprising:
a first conductive layer including a first interstice, wherein the first interstice has a single first width laying in a first plane;
a second conductive layer including a second interstice engaged with the first interstice, wherein the second has a single second width laying in a second plane; and
a dielectric layer disposed between the first and second interstices, wherein the first and second planes are substantially parallel, and wherein the first width substantially overlaps the second width.

19. The circuit board of claim 18, wherein the first and second conductive layers are horizontally-opposed.

20. The circuit board of claim 18, wherein the first and second conductive layers are vertically-overlapping.
